(19) United States
(12) Patent Application Publication
(10) Pub. No.: US 2024/0276125 A1
(43) Pub. Date: Aug. 15, 2024

(54) TELECOMMUNICATIONS EQUIPMENT SHELF WITH INTEGRATED POWER AND COOLING

(71) Applicant: Level 3 Communications, LLC, Broomfield, CO (US)

(72) Inventor: Joel S. Skoglund, Brighton, CO (US)

(73) Assignee: Level 3 Communications, LLC, Broomfield, CO (US)

(21) Appl. No.: 18/339,656

(22) Filed: Jun. 22, 2023

Related U.S. Application Data
(60) Provisional application No. 63/484,153, filed on Feb. 9, 2023.

(51) Int. Cl. H04Q 1/02; H05K 7/14; H05K 7/20

(52) U.S. Cl. CPC H04Q 1/03; H04Q 1/035; H05K 7/1487; H05K 7/1489; H05K 7/1492; H05K 7/20172

(57) ABSTRACT

Novel tools and techniques are provided for implementing telecommunications equipment shelf with integrated power and cooling. In various embodiments, a shelf for a telecommunications equipment mounting structure may be provided that includes one or more power outlets integrated within a body of the shelf, either on a front surface or a rear surface thereof, or both. Each power outlet may include a plurality of receptacles, each of which may be configured, when connected to an authenticated user device via network connectors that are integrated in the body of the shelf and via network cables, to send status information associated with the receptacle and/or its power outlet. In some cases, each shelf may further include a plurality of fans that is also integrated within the body of the shelf to provide air ventilation to cool one or more devices that may be held, supported, and/or mounted on the shelf.

### CROSS-REFERENCES TO RELATED APPLICATIONS

This application claims priority to U.S. Patent Application Ser. No. 63/484,153 (the “'153 Application”), filed Feb. 9, 2023, by Joel S. Skoglund (attorney docket no. 1771-US-P1), entitled, “Telecommunications Equipment Shelf with Integrated Power and Cooling,” the disclosure of which is incorporated herein by reference in its entirety for all purposes.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to systems and apparatuses for implementing telecommunications equipment mounting and placement, and, more particularly, to systems and apparatuses for implementing telecommunications equipment shelf with integrated power and cooling.

### BACKGROUND

In conventional horizontal server and modem racks, power strips that are available are typically vertical power strips that are built into the structure or external yet temporarily mounted to the structure. Such vertical power strips provide a limited number of power outlets that are inconveniently located relative to equipment on the shelves of the racks that require electrical power. Although horizontal power bars are available for racks, such conventional horizontal power bars are not integrated with the shelves of racks. Although fan strips are also available, such conventional fan strips are likewise not integrated with the shelves of racks. It is with respect to this general technical environment to which aspects of the present disclosure are directed.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components. For denoting a plurality of components, the suffixes “a” through “n” may be used, where n denotes any suitable integer number (unless it denotes the number 14, if there are components with reference numerals having suffixes “a” through “m” preceding the component with the reference numeral having a suffix “n”), and may be either the same or different from the suffix “n” for other components in the same or different figures. For example, for component #1 X05a-X05n, the integer value of n in X05n may be the same or different from the integer value of n in X10n for component #2 X10a-X10n, and so on.

FIGS. 1A-1E are schematic diagrams illustrating a non-limiting example of a telecommunications equipment shelf, in accordance with various embodiments, in accordance with various embodiments.

FIGS. 2A-2E are schematic diagrams illustrating another non-limiting example of a telecommunications equipment shelf, in accordance with various embodiments, in accordance with various embodiments.

FIGS. 3A-3J are schematic diagrams illustrating various non-limiting examples of telecommunications equipment shelves having various different component configurations, in accordance with various embodiments, in accordance with various embodiments.

FIGS. 4A and 4B are schematic diagrams illustrating various non-limiting examples of telecommunications equipment mounting structures on which may be mounted various non-limiting examples of telecommunications equipment shelves, in accordance with various embodiments, in accordance with various embodiments.

### DETAILED DESCRIPTION OF CERTAIN EMBODIMENTS

### Overview

Various embodiments provide tools and techniques for implementing telecommunications equipment mounting and placement, and, more particularly, to systems and apparatuses for implementing telecommunications equipment shelf with integrated power and cooling.

In various embodiments, a shelf for a telecommunications equipment mounting structure may be provided that includes one or more power outlets integrated within a body of the shelf, either on a front surface of a body of the shelf, on a rear surface of the body, or both the front and rear surfaces of the body. Each power outlet may include a plurality of receptacles. In some instances, each receptacle may be configured, when connected to one or more authenticated user devices via network connectors that are integrated in the body of the shelf and via network cables (and, in some cases, a network), to send status information associated with either the receptacle and/or the power outlet of which it is a part. In some cases, each shelf may further include a plurality of fans that is also integrated within the body of the shelf to provide air ventilation to cool one or more devices that may be held, supported, and/or mounted on the shelf.

The use of a shelf that has integrated power outlets provides for a greater number of receptacles into which devices held, supported, and/or mounted on the shelf may be plugged, while reduce the footprint thereof, thereby also avoiding cable clutter and competing power connection (and use of outlet splitters, which may result in sometimes dangerous power draws, or the like) of devices. The integration of fans further reduces footprint of support equipment for cooling the devices on the telecommunications equipment mounting structures (e.g., racks, enclosures, and/or cabinets, or the like).

These and other aspects of the telecommunications equipment shelf with integrated power and cooling are described in greater detail with respect to the figures.

The following detailed description illustrates a few exemplary embodiments in further detail to enable one of skill in the art to practice such embodiments. The described examples are provided for illustrative purposes and are not intended to limit the scope of the invention.

In the following description, for the purposes of explanation, numerous specific details are set forth in order to provide a thorough understanding of the described embodiments. It will be apparent to one skilled in the art, however, that other embodiments of the present invention may be practiced without some of these specific details. In other instances, certain structures and devices are shown in block diagram form. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

Unless otherwise indicated, all numbers used herein to express quantities, dimensions, and so forth used should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically stated otherwise.

In an aspect, a shelf for a telecommunications equipment mounting structure is provided. The shelf may comprise a body having a front surface, a rear surface, and a platform, the platform having a top surface. The platform may be configured to hold, support, and/or mount one or more telecommunications equipment on its top surface. The top surface of the platform may face a first direction that is perpendicular to each of a second direction in which the front surface of the body faces and a third direction in which the rear surface of the body faces. The shelf may further comprise one or more mounting points that are configured to mount the shelf to the telecommunications equipment mounting structure; and at least one power outlet that is integrated within the body of the shelf, each power outlet comprising a plurality of receptacles. Each receptacle may extend from one of the front surface or the rear surface of the body, each receptacle being arranged side by side in a horizontal direction along one of the front surface or the rear surface, and each receptacle being configured to receive and fit a power plug of an electronic device.

In some embodiments, the telecommunications equipment mounting structure may comprise one of a two-post telecommunications equipment rack, a four-post telecommunications equipment rack, a telecommunications equipment cabinet, or a telecommunications equipment enclosure, and/or the like. In some instances, the electronic device may comprise telecommunications equipment that is placed on, supported by, or mounted to the platform of the body of the shelf. In some cases, the one or more telecommunications equipment may comprise at least one of one or more servers, one or more central processing units (“CPUs”), one or more modems, one or more routers, one or more network switches, one or more network monitoring devices, or one or more performance monitoring devices, and/or the like. In some examples, the one or more mounting points may comprise mounting points of one or more brackets.

According to some embodiments, the shelf may further comprise a set of adjustable rails that are configured to mount between the body of the shelf and the one or more mounting points, and that are configured, when installed, to enable the body of the shelf to be moved, and set or locked at two or more positions, along the second direction and/or the third direction, relative to the telecommunications equipment mounting structure.

In some instances, the platform may further include a bottom surface, the top surface of the platform corresponding to a top surface of the body, the bottom surface of the platform corresponding to a bottom surface of the body. In some examples, the shelf may further comprise a plurality of fans that is integrated within the body of the shelf. The platform may include a first plurality of openings in the top surface and a second plurality of openings in the bottom surface. Each fan of the plurality of fans may be configured to, when actuated, direct air in through the second plurality of openings, through the body of the shelf, and out of the first plurality of openings toward any one or more objects or devices that are placed on, supported by, or mounted to the top surface of the platform. In some cases, the shelf may further comprise a power distribution device that is integrated within the body, the power distribution device being configured to electrically couple and power one or more of each of the at least one power outlet or each of the plurality of fans. Electrical coupling between the power distribution device and the one or more of each of the at least one power outlet or each of the plurality of fans may be consolidated within the body of the shelf. The power distribution device may comprise one or more power cables that are each configured to extend below the shelf to connect with a power outlet that is external to the telecommunications equipment mounting structure.

In some embodiments, the shelf may further comprise one or more network connectors, each network connector communicatively coupled to one of each power outlet or one or more receptacles among the plurality of receptacles of each power outlet. Each receptacle of the one or more receptacles may be configured to send status information to one or more authenticated user devices via a network connector among the one or more network connectors and via a network cable that is communicatively coupled with said network connector. In some instances, the status information may comprise at least one of whether a device is connected to said receptacle, whether one or more devices are connected to said power outlet, amount of power consumed by a device connected to said receptacle, average amount of power consumed by the device connected to said receptacle, amount of power consumed by the device connected to said receptacle over a first period, amount of power consumed by one or more devices connected to said power outlet, average amount of power consumed by the one or more devices connected to said power outlet, amount of power consumed by the one or more devices connected to said power outlet over a second period, or error data, and/or the like.

In another aspect, a telecommunications equipment mounting structure is provided. The telecommunications equipment mounting structure may comprise one or more vertical support structures and a plurality of shelves. The plurality of shelves may comprise at least one first shelf, comprising a body having a front surface, a rear surface, and a platform, the platform having a top surface, the platform being configured to hold, support, and/or mount one or more telecommunications equipment on its top surface, the top surface of the platform facing a first direction that is perpendicular to each of a second direction in which the front surface of the body faces and a third direction in which the rear surface of the body faces; one or more mounting points that are configured to mount the at least one first shelf to the one or more vertical support structures of the telecommunications equipment mounting structure; and at least one power outlet that is integrated within the body of the at least one first shelf, each power outlet comprising a plurality of receptacles, each receptacle extending from one of the front surface or the rear surface of the body, each receptacle being arranged side by side in a horizontal direction along one of the front surface or the rear surface, and each receptacle being configured to receive and fit a power plug of an electronic device.

In some embodiments, the telecommunications equipment mounting structure may comprise one of a two-post telecommunications equipment rack, a four-post telecommunications equipment rack, a telecommunications equipment cabinet, or a telecommunications equipment enclosure, and/or the like. The one or more vertical support structures of the two-post telecommunications equipment rack may comprise two vertical posts. The one or more vertical support structures of the four-post telecommunications equipment rack may comprise four vertical posts. The one or more vertical support structures of the telecommunications equipment cabinet may comprise one or more cabinet wall mounting structures. The one or more vertical support structures of the telecommunications equipment enclosure may comprise one or more enclosure vertical mounting structures.

According to some embodiments, the telecommunications equipment mounting structure may further comprise a set of adjustable rails that are configured to mount between the body of the shelf and the one or more mounting points, and that are configured, when installed, to enable the body of the shelf to be moved, and set or locked at two or more positions, along the second direction and/or the third direction, relative to the telecommunications equipment mounting structure.

In some instances, the platform may further include a bottom surface, the top surface of the platform corresponding to a top surface of the body, the bottom surface of the platform corresponding to a bottom surface of the body. The at least one first shelf may further comprise a plurality of fans that is integrated within the body of the at least one first shelf. The platform may include a first plurality of openings in the top surface and a second plurality of openings in the bottom surface. Each fan of the plurality of fans may be configured to, when actuated, direct air in through the second plurality of openings, through the body of the at least one first shelf, and out of the first plurality of openings toward any one or more objects or devices that are placed on, supported by, or mounted to the top surface of the platform.

In some cases, the at least one first shelf may further comprise a power distribution device that is integrated within the body, the power distribution device being configured to electrically couple and power one or more of each of the at least one power outlet or each of the plurality of fans. Electrical coupling between the power distribution device and the one or more of each of the at least one power outlet or each of the plurality of fans may be consolidated within the body of the at least one first shelf. The power distribution device may comprise one or more power cables that are each configured to extend below the at least one first shelf to connect with a power outlet that is external to the telecommunications equipment mounting structure.

In some examples, the at least one first shelf may further comprise one or more network connectors, each network connector communicatively coupled to one of each power outlet or one or more receptacles among the plurality of receptacles of each power outlet. Each receptacle of the one or more receptacles may be configured to send status information to one or more authenticated user devices via a network connector among the one or more network connectors and via a network cable that is communicatively coupled with said network connector.

In yet another aspect, a shelf for a telecommunications equipment mounting structure is provided. The shelf may comprise a body having a front surface, a rear surface, and a platform, the platform having a top surface and a bottom surface, the top surface of the platform corresponding to a top surface of the body, the bottom surface of the platform corresponding to a bottom surface of the body. The platform may be configured to hold, support, and/or mount one or more telecommunications equipment on its top surface, the top surface of the platform facing a first direction that is perpendicular to each of a second direction in which the front surface of the body faces and a third direction in which the rear surface of the body faces. The shelf may also comprise one or more mounting points of one or more brackets that are configured to mount the shelf to the telecommunications equipment mounting structure; and at least one power outlet that is integrated within the body of the shelf, each power outlet comprising a plurality of receptacles. Each receptacle may extend from one of the front surface or the rear surface of the body, each receptacle being arranged side by side in a horizontal direction along one of the front surface or the rear surface, and each receptacle being configured to receive and fit a power plug of an electronic device. The shelf may further comprise a plurality of fans that is integrated within the body of the shelf, the platform including a first plurality of openings in the top surface and a second plurality of openings in the bottom surface. Each fan of the plurality of fans may be configured to, when actuated, direct air in through the second plurality of openings, through the body of the shelf, and out of the first plurality of openings toward any one or more objects or devices that are placed on, supported by, or mounted to the top surface of the platform.

In some embodiments, the shelf may further comprise a set of adjustable rails that are configured to mount between the body of the shelf and the one or more mounting points, and that are configured, when installed, to enable the body of the shelf to be moved, and set or locked at two or more positions, along the second direction and/or the third direction, relative to the telecommunications equipment mounting structure.

According to some embodiments, the shelf may further comprise a power distribution device that is integrated within the body, the power distribution device being configured to electrically couple and power one or more of each of the at least one power outlet or each of the plurality of fans. Electrical coupling between the power distribution device and the one or more of each of the at least one power outlet or each of the plurality of fans may be consolidated within the body of the shelf. The power distribution device may comprise one or more power cables that are each configured to extend below the shelf to connect with a power outlet that is external to the telecommunications equipment mounting structure.

In some examples, the shelf may further comprise one or more network connectors, each network connector communicatively coupled to one of each power outlet or one or more receptacles among the plurality of receptacles of each power outlet. Each receptacle of the one or more receptacles may be configured to send status information to one or more authenticated user devices via a network connector among the one or more network connectors and via a network cable that is communicatively coupled with said network connector.

Various modifications and additions can be made to the embodiments discussed without departing from the scope of the invention. For example, while the embodiments described above refer to particular features, the scope of this invention also includes embodiments having different combination of features and embodiments that do not include all of the above-described features.

### Specific Exemplary Embodiments

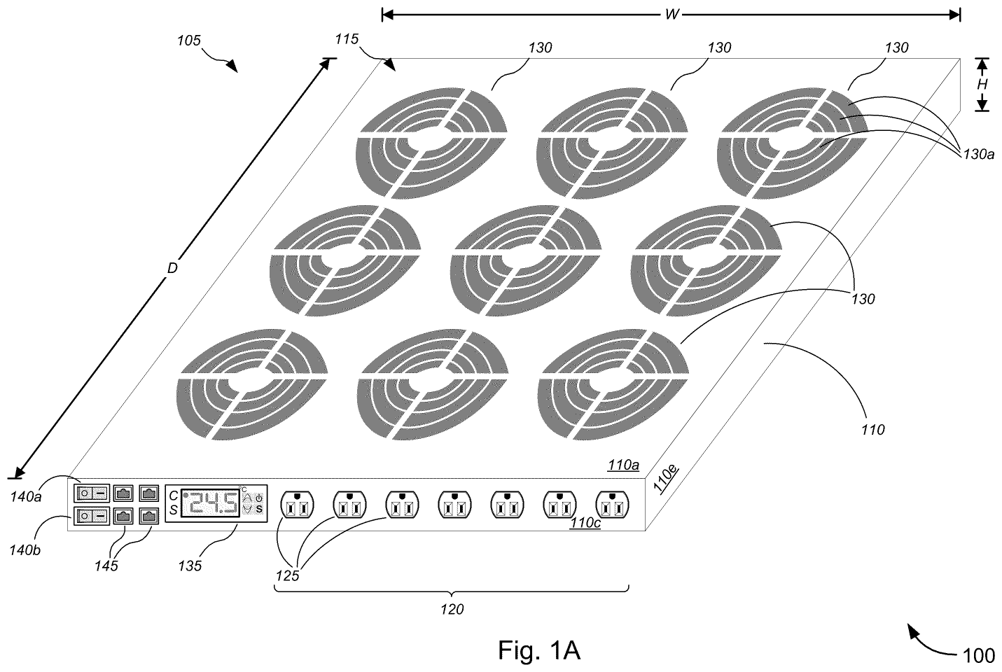

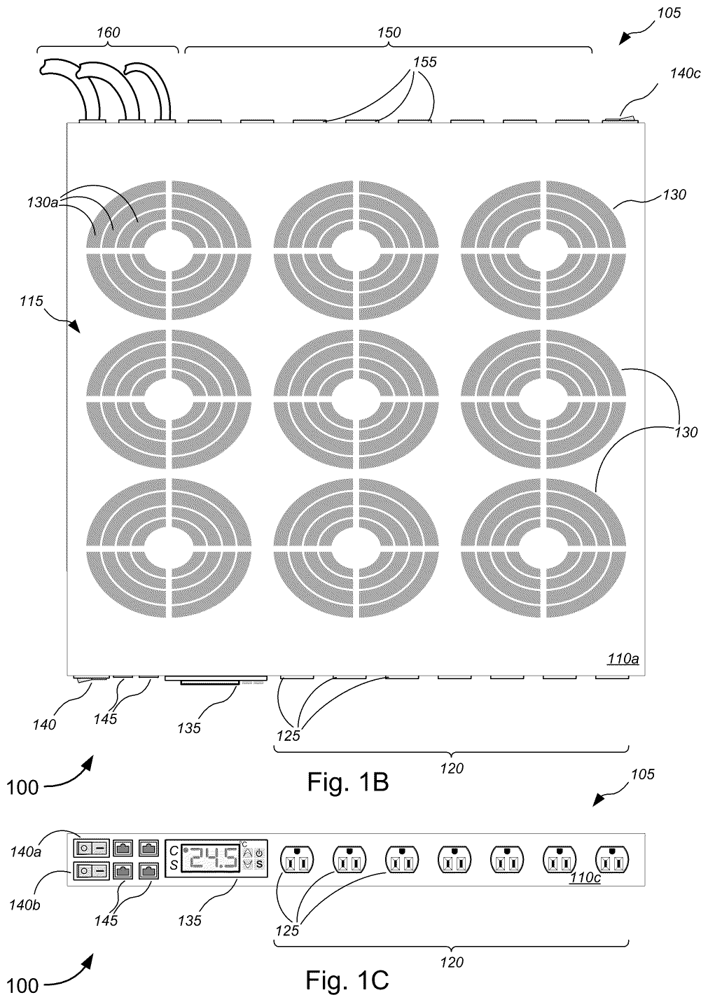

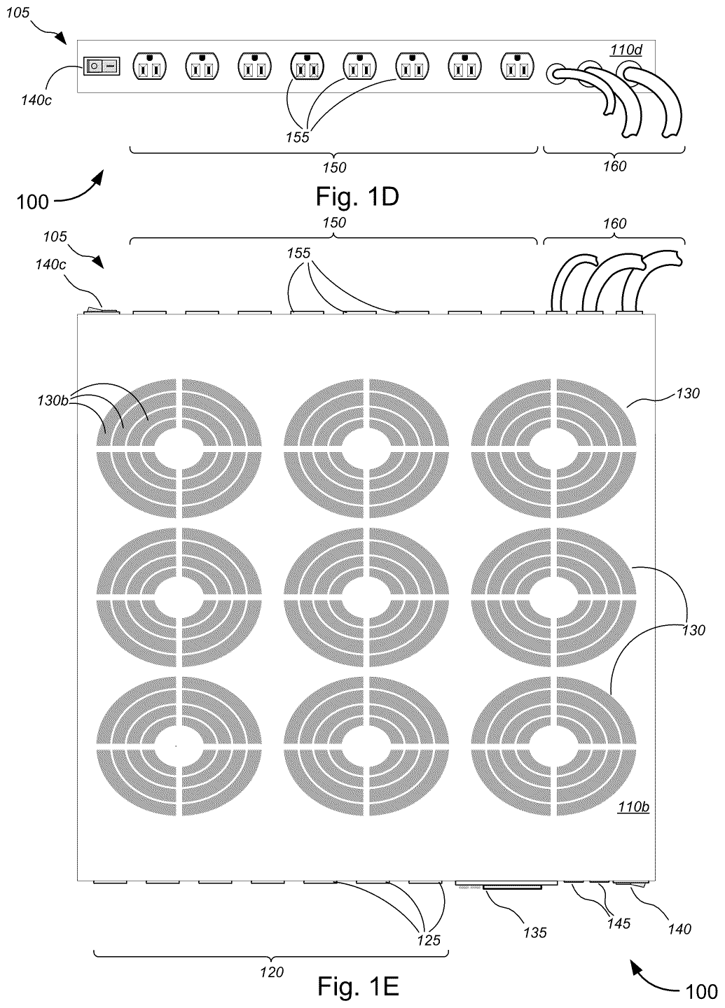

We now turn to the embodiments as illustrated by the drawings. FIGS. 1-4 illustrate some of the features of the systems and apparatuses for implementing telecommunications equipment mounting and placement, and, more particularly, to systems and apparatuses for implementing telecommunications equipment shelf with integrated power and cooling, as referred to above. The methods, systems, and apparatuses illustrated by FIGS. 1-4 refer to examples of different embodiments that include various components and/or steps, which can be considered alternatives or which can be used in conjunction with one another in the various embodiments. The description of the illustrated methods, systems, and apparatuses shown in FIGS. 1-4 is provided for purposes of illustration and should not be considered to limit the scope of the different embodiments.

FIGS. 1-4 are not necessarily intended to be to scale or to depict every feature or detailed characteristic of the various embodiments. Rather, FIGS. 1-4 are intended to be illustrative of the concept of telecommunications equipment shelf with integrated power and/or cooling, in accordance with the various embodiments.

With reference to the figures, FIGS. 1A-IE (collectively, “FIG. 1”) are schematic diagrams illustrating a non-limiting example 100 of a telecommunications equipment shelf, in accordance with various embodiments, in accordance with various embodiments. FIG. 1A is an oblique projection drawing of a non-limiting example of a telecommunications equipment shelf, in accordance with various embodiments. FIG. 1B depicts a top plan view of the telecommunications equipment shelf of FIG. 1A, in accordance with various embodiments. FIG. 1C depicts a front elevation view of the telecommunications equipment shelf of FIG. 1A, in accordance with various embodiments. FIG. 1D depicts a rear elevation view of the telecommunications equipment shelf of FIG. 1A, in accordance with various embodiments. FIG. 1E depicts a bottom plan view of the telecommunications equipment shelf of FIG. 1A, in accordance with various embodiments.

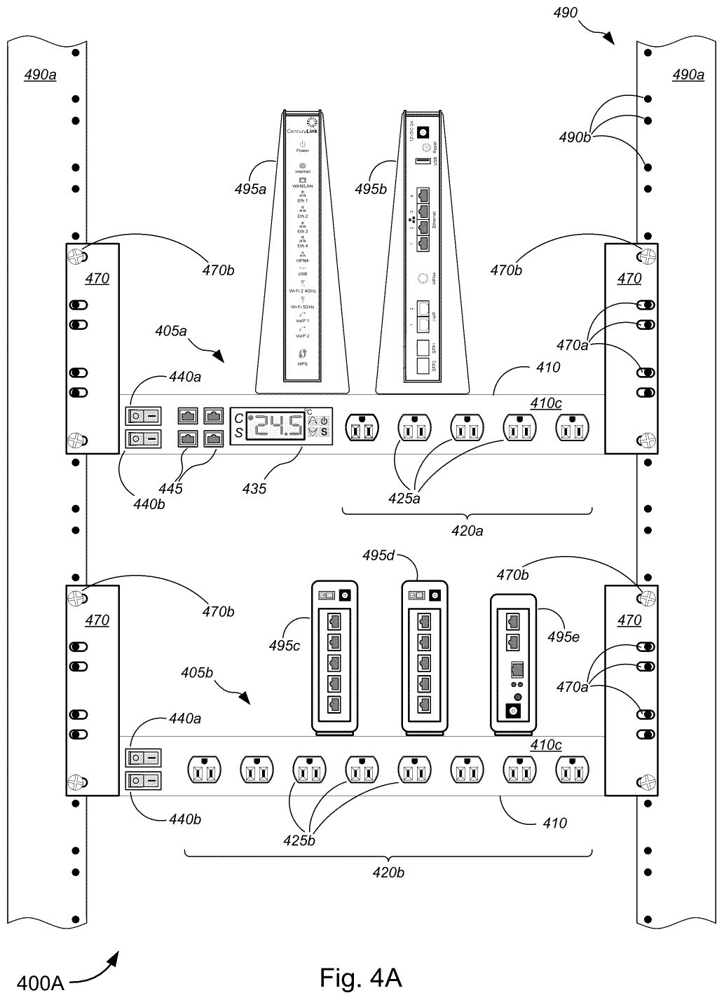

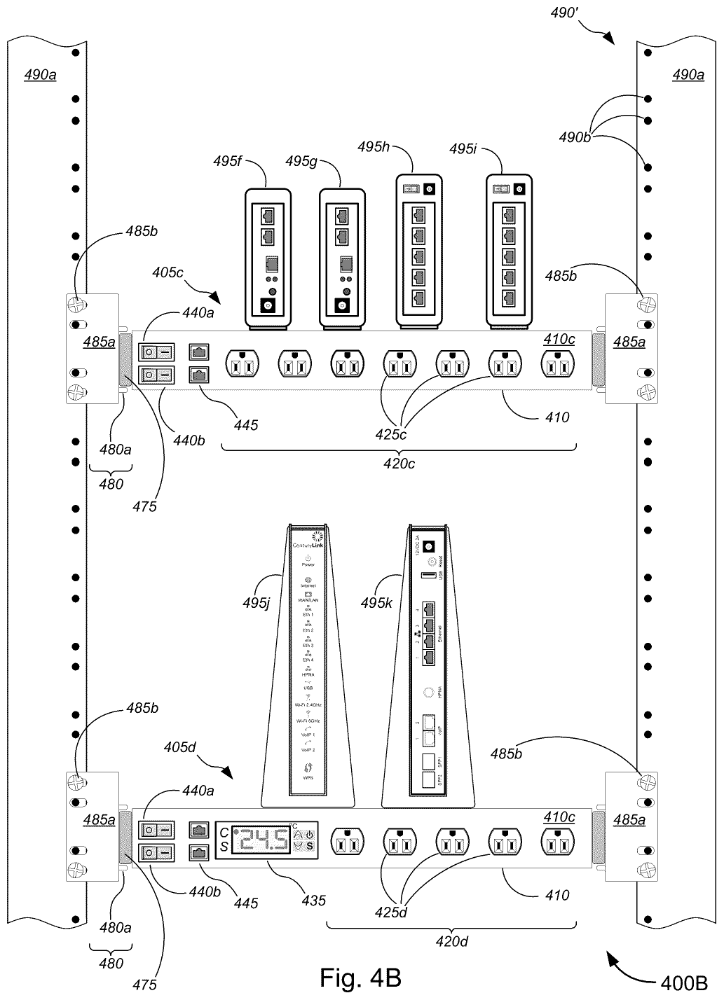

In the non-limited example 100 of FIG. 1, a shelf 105 for a telecommunications equipment mounting structure is shown. The shelf 105 may include a body 110 having a front surface 110c, a rear surface 110d, and a platform 115, the platform 115 having a top surface 110a and a bottom surface 110b, the top surface 110a of the platform 115 corresponding to a top surface 110a of the body 110, the bottom surface 110b of the platform 115 corresponding to a bottom surface 110b of the body 110. The platform 115 may be configured to hold, support, and/or mount one or more telecommunications equipment (including, but not limited to, telecommunications equipment 495a-495k of FIGS. 4A and 4B, or the like) on its top surface 110a, the top surface 110a of the platform 115 facing a first direction that is perpendicular to each of a second direction in which the front surface 110c of the body 110 faces and a third direction in which the rear surface 110d of the body 110 faces. In some examples, the body 110 may have a height (denoted by dimension marker “H” in FIG. 1) of about 1, 2, 3, or 4 inches (or about 2.5, 5.1, 7.6, or 10.2 cm) or within a range between about 0.5 and 4 inches (or between about 1.3 and about 10.2 cm), or the like, a width (denoted by dimension marker “W” in FIG. 1) of about 19 inches or about 23 inches (or about 48.3 cm or about 58.4 cm) or within a range between about 12 and about 36 inches (or between about 30.5 and about 91.4 cm), or the like, and a depth (denoted by dimension marker “D” in FIG. 1) of about 18 inches or about 24 inches (or about 45.7 cm or about 61.0 cm) or within a range between about 12 and about 36 inches (or between about 30.5 and about 91.4 cm), or the like.

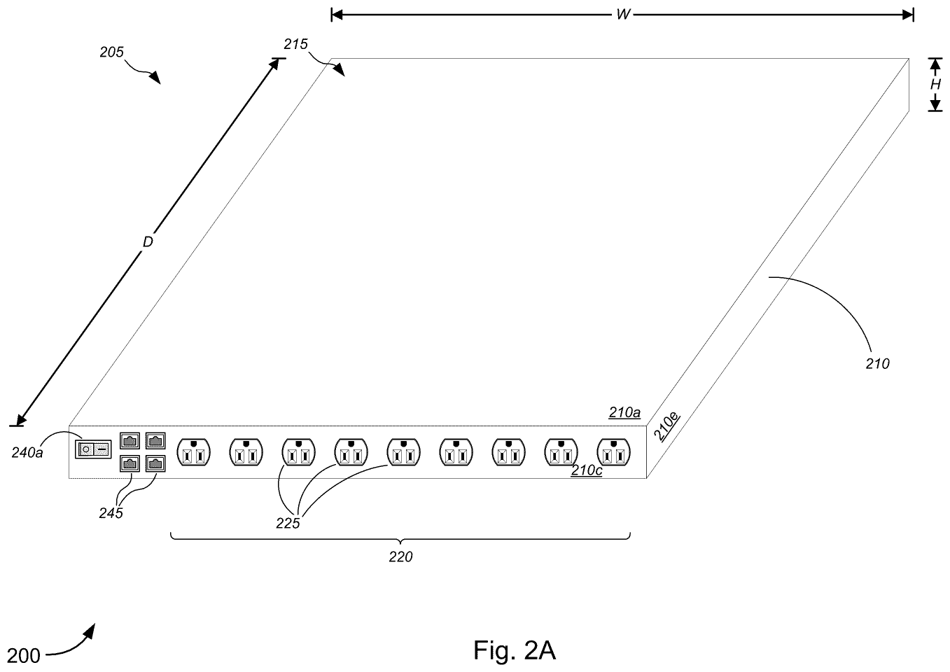

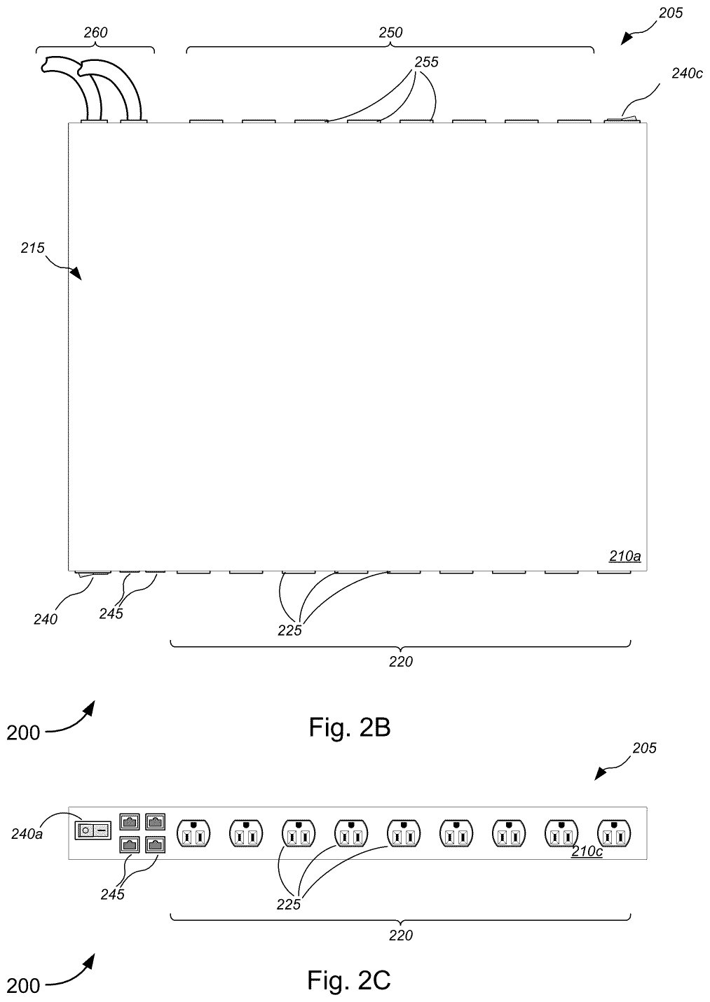

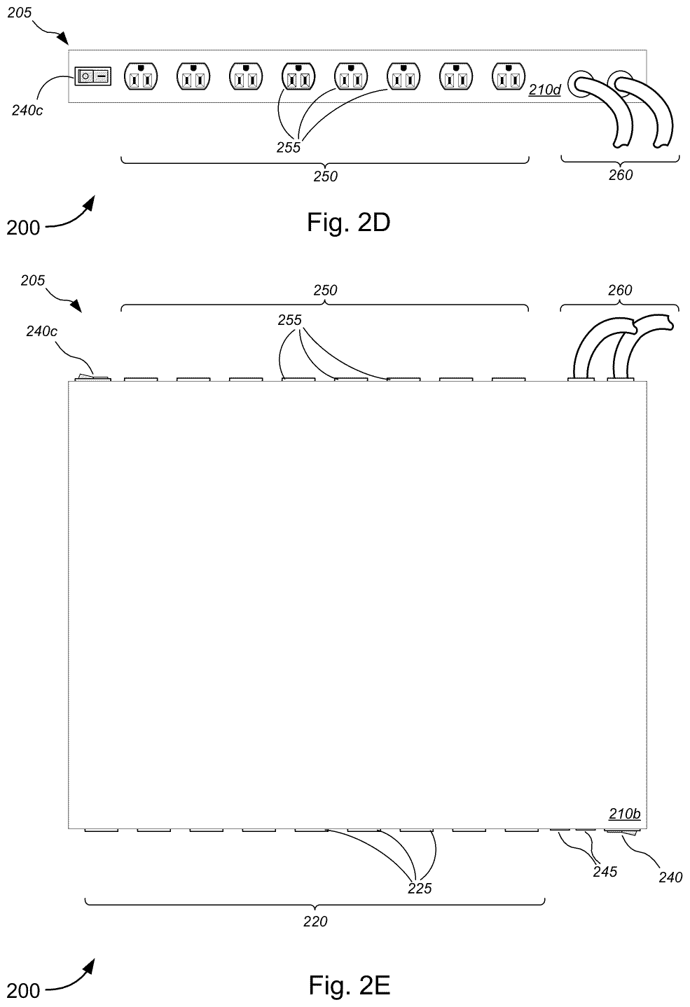

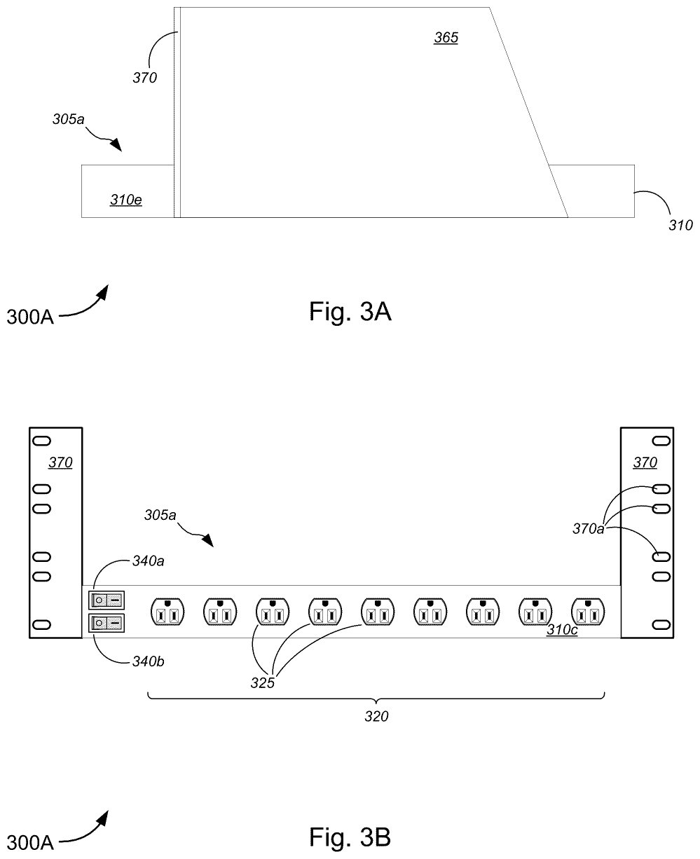

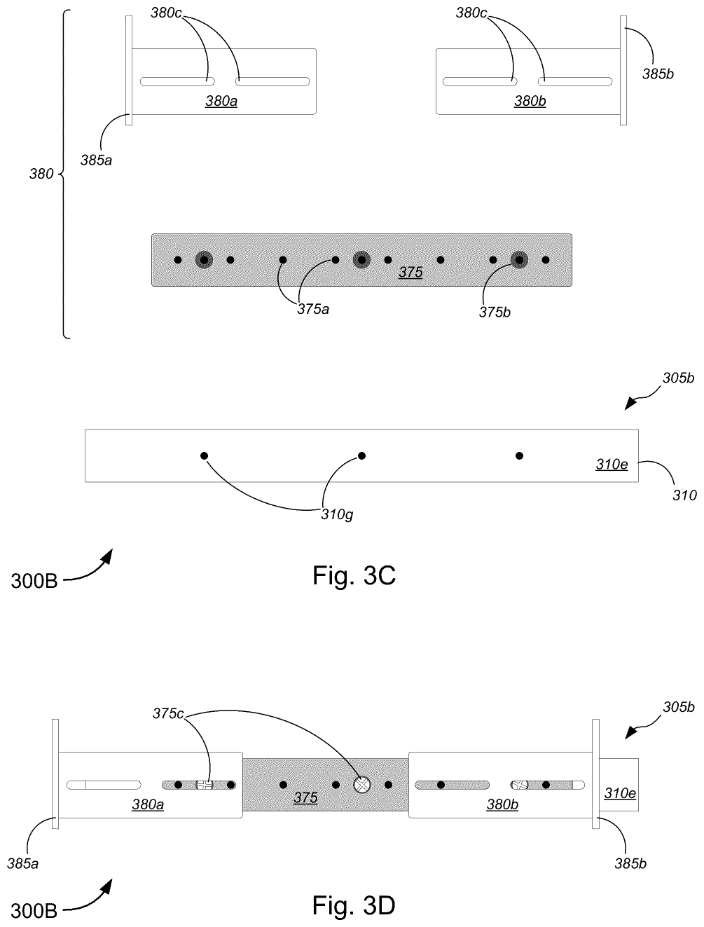

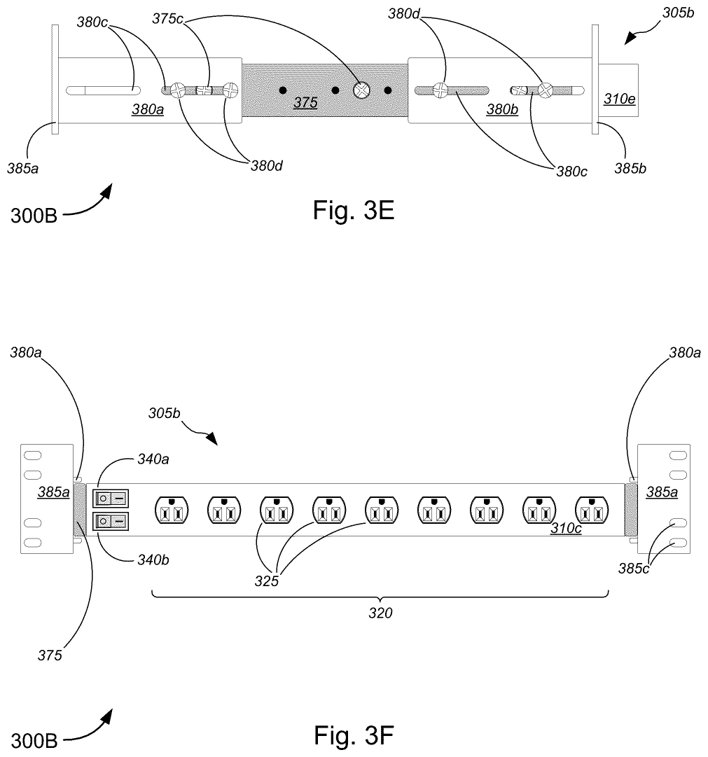

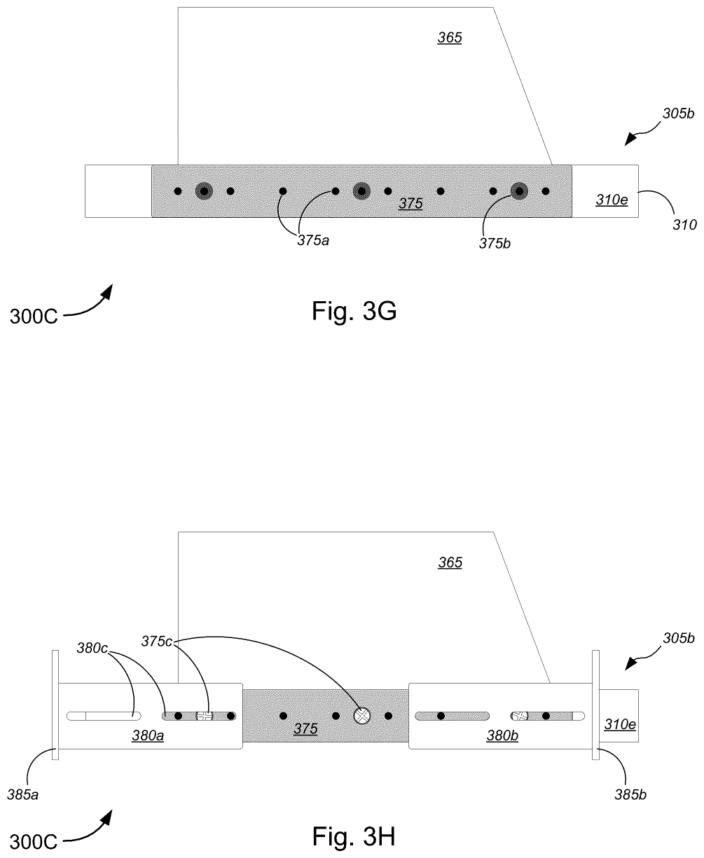

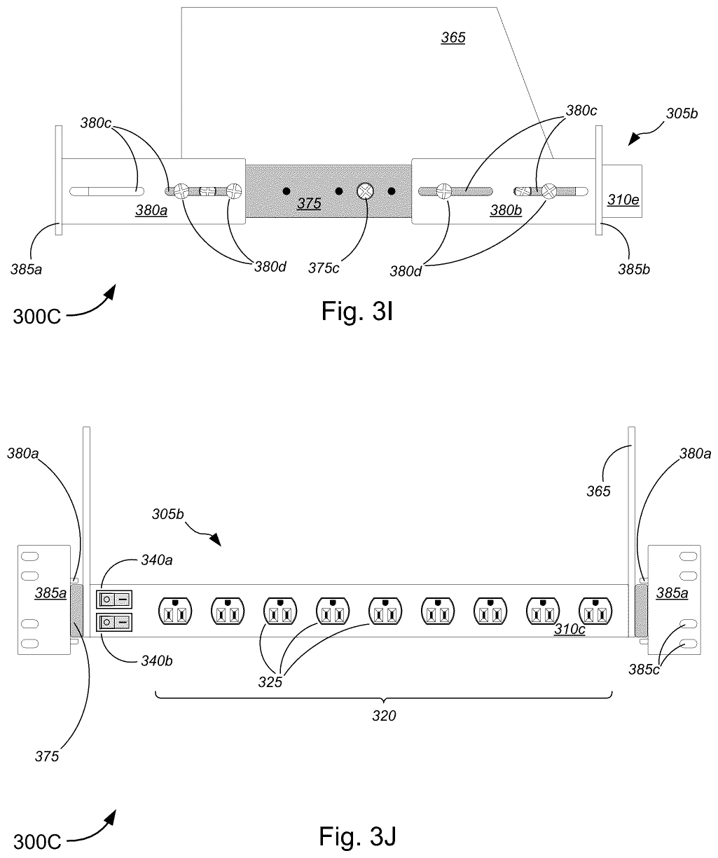

The shelf 105 may also include one or more mounting points of one or more brackets (including, but not limited to, brackets 370, 385, 470, and 485 of FIGS. 3B-3F, 3H-3J, 4A and 4B, or the like) that are configured to mount the shelf 105 to the telecommunications equipment mounting structure (e.g., telecommunications equipment mounting structure 490 and 490′ of FIGS. 4A and 4B, or the like); and at least one power outlet 120 and/or 150 (similar to power outlets 220, 250, 320, and/or 420a-420d of FIGS. 2-4, or the like) that is integrated within the body 110 of the shelf 105, each power outlet 120 and/or 150 including a plurality of receptacles 125 and/or 155 (similar to receptacles 225, 255, 325, and/or 425a-425d of FIGS. 2-4, or the like). Each receptacle may extend from one of the front surface 110c (e.g., in the case of receptacles 125, or the like) or the rear surface 110d (e.g., in the case of receptacles 155, or the like) of the body 110, each receptacle being arranged side by side in a horizontal direction along one of the front surface or the rear surface (as shown, e.g., in FIGS. 1A, 1C, and ID, or the like), and each receptacle being configured to receive and fit a power plug (not shown) of an electronic device (including, but not limited to, 495a-495k of FIGS. 4A and 4B, or the like).

In some embodiments, the telecommunications equipment mounting structure may include, without limitation, one of a two-post telecommunications equipment rack, a four-post telecommunications equipment rack, a telecommunications equipment cabinet, or a telecommunications equipment enclosure, and/or the like. In some cases, the one or more vertical support structures of the two-post telecommunications equipment rack may include two vertical posts. In some examples, the one or more vertical support structures of the four-post telecommunications equipment rack may include four vertical posts. In some cases, the one or more vertical support structures of the telecommunications equipment cabinet may include one or more cabinet wall mounting structures. In some examples, the one or more vertical support structures of the telecommunications equipment enclosure may include one or more enclosure vertical mounting structures. And so on.

In some instances, the electronic device may include, but is not limited to, telecommunications equipment that is placed on, supported by, or mounted to the platform of the body of the shelf. In some cases, the one or more telecommunications equipment may include, without limitation, at least one of one or more servers, one or more central processing units (“CPUs”), one or more modems, one or more routers, one or more network switches, one or more network monitoring devices, or one or more performance monitoring devices, and/or the like. Alternatively, the electronic device may include any suitable electronic device or equipment that can fit on a telecommunications equipment mounting structure, or the like.

According to some embodiments, the shelf 105 may further include a plurality of fans 130 that is integrated within the body 110 of the shelf 105, the platform 115 including a first plurality of openings 130a in the top surface 110a and a second plurality of openings 130b in the bottom surface 110b. Each fan 130 of the plurality of fans 130 may be configured to, when actuated, direct air in through the second plurality of openings 130b, through the body 110 of the shelf 105, and out of the first plurality of openings 130a toward any one or more objects or devices (including, but not limited to, 495a-495k of FIGS. 4A and 4B, or the like) that are placed on, supported by, or mounted to the top surface 110a of the platform 115. Although not shown, each fan 130 may include a motor, fan blades, mounting parts, electronics components, and/or the like. In some instances, the shelf 105 may further include a control panel 135 for manually controlling the plurality of fans 130, the control panel 135 including, without limitation, at least one of a display screen (including, but not limited to, a liquid crystal display (“LCD”) device, a light emitting diode (“LED”) display device, an organic LED (“oLED”) display device, and/or the like; displaying at least one of a user-set temperature, a current temperature, indicator indicating which of these temperatures is being displayed, or the like), and/or one or more buttons (either physical or virtual buttons, including, but not limited to, at least one of a control panel power button, a set temperature button, an increase temperature button, or a decrease temperature button, or the like), or the like.

In some examples, the shelf 105 may further include one or more network connectors 145, each network connector 145 communicatively coupled to one of each power outlet 120 and/or 150 or one or more receptacles 125 and/or 155 among the plurality of receptacles of each power outlet. Each receptacle 125 and/or 155 of the one or more receptacles may be configured to send status information to one or more authenticated user devices via a network connector among the one or more network connectors and via a network cable (not shown) that is communicatively coupled with said network connector. In some instances, the status information may include, but is not limited to, at least one of whether a device is connected to said receptacle, whether one or more devices are connected to said power outlet, amount of power consumed by a device connected to said receptacle, average amount of power consumed by the device connected to said receptacle, amount of power consumed by the device connected to said receptacle over a first period, amount of power consumed by one or more devices connected to said power outlet, average amount of power consumed by the one or more devices connected to said power outlet, amount of power consumed by the one or more devices connected to said power outlet over a second period, or error data, and/or the like.

In some embodiments, the shelf 105 may further include one or more power buttons 140 (which are depicted in FIG. 1 as rocker-style buttons 140a, 140b, and 140c, although not limited to such type of button) that provide power to at least one of the plurality of fans and/or one or more power outlets to be physically switched on or off, in some cases, with indicator lights to indicate whether or not power is going to the plurality of fans and/or to one or more power outlets (as a safety feature, or the like). In some instances, the shelf 105 may further include a power distribution device (not shown) that is integrated within the body 110, the power distribution device being configured to electrically couple and power one or more of each of the at least one power outlet 120, 150 or each of the plurality of fans 130. In some cases, at least one power button 140 may alternatively or additionally be used to provide power to the power distribution device. Electrical coupling between the power distribution device and the one or more of each of the at least one power outlet or each of the plurality of fans may be consolidated within the body 110 of the shelf 105. The power distribution device may include one or more power cables 160 that are each configured to extend below the shelf 105 to connect with a power outlet (not shown) that is external to the telecommunications equipment mounting structure. In some cases, at least one power cable 160 among the one or more power cables 160 may include, without limitation, a cable rated for at least 20 Amps (such as, but not limited to, a National Electrical Manufacturers Association (“NEMA”) L5-20 cable with a L5-20R receptacle and/or L5-20P plug, or the like), a cable rated for at least 30 Amps (such as, but not limited to, a NEMA L5-30 cable with a L5-30R receptacle and/or L5-30P plug, or the like), a cable rated for at least 50 Amps (such as, but not limited to, a NEMA L5-50 cable with a L5-50R receptacle and/or L5-50P plug, or the like), a cable rated for amperage lower than 20 Amps (e.g., for fans and other accessories, etc.), or a cable rated for amperage higher than 50 Amps (e.g., for the power outlets, etc.), or the like. In some instances, the power outlets 120 and/or 150 may similarly be rated for at least one 20 Amps (in some cases, at least 30 Amps, or at least 50 Amps, or greater), or the like.

These and other functions or features of the example 100 (and its components) are described in greater detail below with respect to FIGS. 2-4.

FIGS. 2A-2E (collectively, “FIG. 2”) are schematic diagrams illustrating another non-limiting example 200 of a telecommunications equipment shelf, in accordance with various embodiments, in accordance with various embodiments. FIG. 2A is an oblique projection drawing of a non-limiting example of a telecommunications equipment shelf, in accordance with various embodiments. FIG. 2B depicts a top plan view of the telecommunications equipment shelf of FIG. 2A, in accordance with various embodiments. FIG. 2C depicts a front elevation view of the telecommunications equipment shelf of FIG. 2A, in accordance with various embodiments. FIG. 2D depicts a rear elevation view of the telecommunications equipment shelf of FIG. 2A, in accordance with various embodiments. FIG. 2E depicts a bottom plan view of the telecommunications equipment shelf of FIG. 2A, in accordance with various embodiments.

In the non-limiting example 200 of FIG. 2, shelf 205, body 210, body surfaces 210a-210f, platform 215, platform surfaces 210a and 210b, power outlet(s) 220 and/or 250, receptacles 225 and/or 255, power buttons 240a and 240c, network connectors 245, and power cables 260 of FIG. 2 may otherwise be similar, if not identical, to shelf 105, body 110, body surfaces 110a-110f, platform 115, platform surfaces 110a and 110b, power outlet(s) 120 and/or 150, receptacles 125 and/or 155, power buttons 140a, 140b, and 140c, network connectors 145, and power cables 160, respectively, of example 100 of FIG. 1, and the description of these components of example 100 of FIG. 1 are similarly applicable to the corresponding components of FIG. 2.

The non-limiting embodiment of FIG. 2 differs from that of FIG. 1 in that the embodiment of FIG. 1 has integrated power outlet(s) 120 and 150 and integrated network connector(s) 145 as well as integrated fans 130 (and corresponding control panel 135), whereas the embodiment of FIG. 2 has integrated power outlet(s) 220 and 250 and integrated network connector(s) 245 without integrated fans (or corresponding control panel). The height, width, and depth of the body 210 of shelf 205 is also similar to those of body 110 of shelf 105, as described above. The shelf 205 of FIG. 2 may otherwise be similar, if not identical, to shelf 105 of FIG. 1. In accordance with the examples depicted in FIGS. 1 and 2, there may be one power outlet on the front surface or one power outlet on the rear surface, or there may be a power outlet on the front surface and a power outlet on the rear surface; each power outlet may have any suitable number of receptacles; there may be any suitable number of network connectors for connecting to one or more of the power outlets and/or receptacles; and there may be any suitable number of power buttons and/or power cables; and/or the like. For the example 100 of FIG. 1, there may be any suitable number of fans 130, and the control panel (if present, although need not be present) may have any suitable number of buttons or options for controlling the fans 130.

These and other functions or features of the example 200 (and its components) are described in greater detail below with respect to FIGS. 1, 3, and 4.

FIGS. 3A-3J (collectively, “FIG. 3”) are schematic diagrams illustrating various non-limiting examples 300A, 300B, and 300C of telecommunications equipment shelves having various different component configurations, in accordance with various embodiments, in accordance with various embodiments.

FIG. 3A is a side elevation view of shelf 305a, while FIG. 3B is a front elevation view of shelf 305a. Example 300A, as shown in FIGS. 3A and 3B, includes shelf 305a having side walls 365 and corresponding brackets 370, which are configured to removably affix shelf 305a to a two-post telecommunications equipment rack (such as the telecommunications equipment rack as shown, e.g., in FIG. 4A, or the like), or the like. In some cases, side walls 365 may be integrally formed with or from the body 310. Alternatively, side walls 365 may be removably affixed to body 310, in some cases, in a manner similar to removably affixing mounting bars 375 to body 310, as shown and described below with respect to example 300B in FIGS. 3C-3F, or the like. Similarly, in some cases, brackets 370 may be integrally formed with or from side walls 365. Alternatively, brackets 370 may be removably affixed to side walls 365, in some cases, in a manner similar to removably affixing mounting bars 375 to body 310 or removably affixing side walls 365 to body 310, and, in some cases, using corresponding nuts to engage with set screws to hold the brackets 370 to the side walls 365. Shelf 305a is otherwise similar, if not identical, to shelf 105 of example 100 of FIG. 1 or shelf 205 of example 200 of FIG. 2. Reference numerals in FIGS. 3A and 3B correspond to similar reference numerals in FIGS. 1 and 2 (e.g., power outlet 320, receptacles 325, front surface 310c, side surface 310e, and power buttons 340a and 340b are similar, if not identical, to power outlet 120 or 220, receptacles 125 or 225, front surface 110c or 210c, side surface 110e or 210e, and power buttons 140a-140c or 240a and 240c, respectively).

FIGS. 3C-3E are side elevation views of shelf 305b at various stages of attachment of the set of adjustable rails 380 to body 310 of shelf 305b, while FIG. 3F is a front elevation view of shelf 305b. Example 300B, as shown in FIGS. 3C-3F, includes shelf 305b having a set of adjustable rails 380 that are configured to mount between the body 310 of the shelf 305b and the one or more mounting points (e.g., brackets 385a or 385b, each with slots 385c, or mounting points on two or more posts of telecommunications equipment mounting structure as shown, e.g., in FIG. 4B, or the like), or be otherwise removably affixable to shelf 305b. In some examples, the set of adjustable rails 380 (including front rails 380a and rear rails 380b, or the like, with a front rail 380a/rear rail 380b pair on each side surface 310e or 310f of body 310) may be configured, when installed, to enable the body 310 of the shelf 305b to be moved, and set or locked (using set screws 380d) at two or more positions, along the second direction and/or the third direction (e.g., frontward and/or rearward along rail slots 380c), relative to the telecommunications equipment mounting structure (as shown, e.g., in FIG. 4, or the like).

In some cases, the set of adjustable rails 380 may include mounting bars 375 with threaded screw holes 375a and 375b, and with the threaded screw holes 375b being configured to allow set screws 375c to engage therewith and with threaded screw holes 310g in body 310 to secure the mounting bars 375 one on each side surface 310e (shown in FIGS. 3C-3F) and 310f (not shown) of the body 310 of shelf 305b and being configured to allow the set screws 375c to be countersunk below a surface of the mounting bars 375 to avoid interfering with the front rails 380a and the rear rails 380b, and with the threaded screw holes 375a being configured to allow set screws 380d to engage therewith to lock or set front rails 380a and/or rear rails 380b to the mounting bar 375, or the like. In some cases, screw holes 375b may not be threaded, but may be large enough to allow free insertion or extraction of set screws 375c therethrough, with threaded screw holes 310g allowing for set screws 375c to engage therewith thereby securing mounting bars 375 to the side surface 310e and/or 310f of body 310, or the like. Shelf 305b is otherwise similar, if not identical, to shelf 105 of example 100 of FIG. 1 or shelf 205 of example 200 of FIG. 2. Reference numerals in FIGS. 3C-3F correspond to similar reference numerals in FIGS. 1 and 2 (e.g., power outlet 320, receptacles 325, front surface 310c, side surface 310e, and power buttons 340a and 340b are similar, if not identical, to power outlet 120 or 220, receptacles 125 or 225, front surface 110c or 210c, side surface 110e or 210e, and power buttons 140a-140c or 240a and 240c, respectively).

FIGS. 3G-31 are side elevation views of shelf 305c at various stages of attachment of the set of adjustable rails 380 to body 310 of shelf 305c, while FIG. 3J is a front elevation view of shelf 305c. Example 300C, as shown in FIGS. 3G-3J, includes shelf 305c having a combination of the side walls 365 (without corresponding brackets 370) of example 300A and the set of adjustable rails 380 of example 300B. Shelf 305c is otherwise similar, if not identical, to shelf 105 of example 100 of FIG. 1 or shelf 205 of example 200 of FIG. 2. Reference numerals in FIGS. 3G-3J correspond to similar reference numerals in FIGS. 1 and 2 (e.g., power outlet 320, receptacles 325, front surface 310c, side surface 310e, and power buttons 340a and 340b are similar, if not identical, to power outlet 120 or 220, receptacles 125 or 225, front surface 110c or 210c, side surface 110e or 210e, and power buttons 140a-140c or 240a and 240c, respectively).

These and other functions or features of the examples 300A, 300B, and/or 300C (and their components) are described in greater detail below with respect to FIGS. 1, 2, and 4.

FIGS. 4A and 4B (collectively, “FIG. 4”) are schematic diagrams illustrating various non-limiting examples 400A and 400B of telecommunications equipment mounting structures on which may be mounted various non-limiting examples 405a, 405b, 405c, and 405d of telecommunications equipment shelves, in accordance with various embodiments, in accordance with various embodiments. FIG. 4A depicts a telecommunications equipment mounting structure 490 including a two-post telecommunications equipment rack or the like having posts 490a, while FIG. 4B depicts a telecommunications equipment mounting structure 490′ including a four-post (with front two posts 490a shown, rear two posts not shown).

Example 400A of FIG. 4A includes a shelf 405a, with side walls (not shown in FIG. 4) and brackets 470, that is similar to shelf 105 of FIG. 1 combined with the side walls 365 and brackets 370 of shelf 305a of FIGS. 3A and 3B, and a shelf 405b, with side walls (not shown in FIG. 4) and brackets 470, that is similar to shelf 205 of FIG. 2 combined with the side walls 365 and brackets 370 of shelf 305a of FIGS. 3A and 3B. As shown in FIG. 4A, set screws 470b may be used to secure brackets 470 (and thus corresponding shelf 405a or 405b) to posts 490a of telecommunications equipment mounting structure 490, by engaging with two or more screw holes 490b in said posts 490a.

Example 400B of FIG. 4B includes a shelf 405c, with adjustable rails 480 (including brackets 485a (shown in FIG. 4B) and 485b (not shown in FIG. 4B), front rails 480a (shown in FIG. 4B) and rear rails 480b (not shown in FIG. 4B), and mounting bars 475, or the like), that is similar to shelf 205 of FIG. 2 combined with the set of adjustable rails 380 of shelf 305b of FIGS. 3C-3F, and a shelf 405d, with adjustable rails 480 (including brackets 485a (shown in FIG. 4B) and 485b (not shown in FIG. 4B), front rails 480a (shown in FIG. 4B) and rear rails 480b (not shown in FIG. 4B), and mounting bars 475, or the like), that is similar to shelf 105 of FIG. 1 combined with the set of adjustable rails 380 of shelf 305b of FIGS. 3C-3F. As shown in FIG. 4B, set screws 485b may be used to secure brackets 485a (and thus corresponding shelf 405c or 405d) to posts 490a of telecommunications equipment mounting structure 490′, by engaging with two or more screw holes 490b in said posts 490a.

Each shelf 405a-405d (collectively, “shelves 405” or the like) is configured to hold, support, and/or mount one or more devices 495a-495k (collectively, “devices 495” or the like), which may include one or more telecommunications equipment, one or more electronic devices, and/or any suitable device that can fit on the shelf 405a-405d and on the telecommunications equipment mounting structure 490 or 490′. As described above, the one or more telecommunications equipment may include, without limitation, at least one of one or more servers, one or more central processing units (“CPUs”), one or more modems, one or more routers, one or more network switches, one or more network monitoring devices, or one or more performance monitoring devices, and/or the like. With the receptacles 425 of power outlets 420a-420d on the front surface 410c of body 410 of each of shelves 405a-405d, power cables (and their corresponding plugs; both not shown) for each of these devices 495 may be plugged into these receptacles to provide power to these devices 495. Alternatively, although not shown in FIG. 4 (but shown in FIGS. 1 and 2), receptacles 455 of power outlets 450 on the rear surface 410d of body 410 of one or more of these shelves 405a-405d may be used for plugging in (and powering) these devices 495.

In some embodiments, network connectors 445 on shelves 405a, 405c, and 405d, when used to connect to one or more authenticated user devices (not shown) via corresponding network cables (not shown) and, in some cases, to a network (not shown), may allow the receptacles to send status information to the one or more authenticated user devices. As described above, status information may include, but is not limited to, at least one of whether a device is connected to said receptacle, whether one or more devices are connected to said power outlet, amount of power consumed by a device connected to said receptacle, average amount of power consumed by the device connected to said receptacle, amount of power consumed by the device connected to said receptacle over a first period, amount of power consumed by one or more devices connected to said power outlet, average amount of power consumed by the one or more devices connected to said power outlet, amount of power consumed by the one or more devices connected to said power outlet over a second period, or error data, and/or the like.

In some examples, power buttons 440a and 440b (collectively, “power buttons 440” or the like) may provide power to at least one of the plurality of fans 430 (if present, shown in FIG. 1 as fans 130) and/or one or more power outlets 420 (and/or 450 (shown in FIGS. 1 and 2 as power outlets 150 and 250)) to be physically switched on or off, in some cases, with indicator lights to indicate whether or not power is going to the plurality of fans and/or to the one or more power outlets (as a safety feature, or the like), and/or to provide power to a power distribution device (not shown) that is described above with respect to FIG. 1, or the like.

According to some embodiments, each shelf 405a-405d may have an appropriate height, width, and depth of its body 410 (similar to those of body 110 of shelf 105, as described above with respect to FIG. 1) to fit within telecommunications equipment mounting structure 490 or 490′. Each shelf 405a-405d may use a front surface power outlet 420 only (as shown in FIG. 4), a rear surface power outlet 450 only (not shown in FIG. 4), or both a front surface power outlet 420 and a rear surface power outlet 450. Each power outlet 420 (or 450) may have any suitable number of receptacles 425 (or 455). Each shelf 405a-405d may include any suitable number of power buttons 440, any suitable number of network connectors 445 (if any), and any suitable number of fans 430 (not shown; if any, together with control panel 435). Each shelf 405 may include side walls 465 (not shown) or may exclude side walls 465. Each shelf 405 may include adjustable rails 480 (as shown in FIG. 4B) or exclude adjustable rails 480 (as shown in FIG. 4A). Each shelf 405 may include a power distribution device (not shown) that consolidates electrical coupling between the power distribution device and one or more of each of the at least one power outlet or each of the plurality of fans, or the like, with power cables 560 (shown in FIGS. 1 and 2 as power cables 160 and 260, or the like) extending therefrom to below each shelf 405.

These and other functions or features of the examples 400A and/or 400B (and their components) are described in greater detail below with respect to FIGS. 1-3.

While certain features and aspects have been described with respect to exemplary embodiments, one skilled in the art will recognize that numerous modifications are possible. For example, the methods and processes described herein may be implemented using hardware components, software components, and/or any combination thereof. Further, while various methods and processes described herein may be described with respect to particular structural and/or functional components for ease of description, methods provided by various embodiments are not limited to any particular structural and/or functional architecture but instead can be implemented on any suitable hardware, firmware and/or software configuration. Similarly, while certain functionality is ascribed to certain system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with—or without-certain features for ease of description and to illustrate exemplary aspects of those embodiments, the various components and/or features described herein with respect to a particular embodiment can be substituted, added and/or subtracted from among other described embodiments, unless the context dictates otherwise. Consequently, although several exemplary embodiments are described above, it will be appreciated that the invention is intended to cover all modifications and equivalents within the scope of the following claims.

What is claimed is:

1. A shelf for a telecommunications equipment mounting structure, the shelf comprising:
a body having a front surface, a rear surface, and a platform, the platform having a top surface, the platform being configured to hold, support, and/or mount one or more telecommunications equipment on its top surface, the top surface of the platform facing a first direction that is perpendicular to each of a second direction in which the front surface of the body faces and a third direction in which the rear surface of the body faces;
one or more mounting points that are configured to mount the shelf to the telecommunications equipment mounting structure; and
at least one power outlet that is integrated within the body of the shelf, each power outlet comprising a plurality of receptacles, each receptacle extending from one of the front surface or the rear surface of the body, each receptacle being arranged side by side in a horizontal direction along one of the front surface or the rear surface, and each receptacle being configured to receive and fit a power plug of an electronic device.

2. The shelf of claim 1, wherein the telecommunications equipment mounting structure comprises one of a two-post telecommunications equipment rack, a four-post telecommunications equipment rack, a telecommunications equipment cabinet, or a telecommunications equipment enclosure.

3. The shelf of claim 1, wherein the electronic device comprises telecommunications equipment that is placed on, supported by, or mounted to the platform of the body of the shelf.

4. The shelf of claim 1, wherein the one or more telecommunications equipment comprise at least one of one or more servers, one or more central processing units (“CPUs”), one or more modems, one or more routers, one or more network switches, one or more network monitoring devices, or one or more performance monitoring devices.

5. The shelf of claim 1, wherein the one or more mounting points comprise mounting points of one or more brackets.

6. The shelf of claim 1, further comprising:
a set of adjustable rails that are configured to mount between the body of the shelf and the one or more mounting points, and that are configured, when installed, to enable the body of the shelf to be moved, and set or locked at two or more positions, along the second direction and/or the third direction, relative to the telecommunications equipment mounting structure.

7. The shelf of claim 1, wherein the platform further includes a bottom surface, the top surface of the platform corresponding to a top surface of the body, the bottom surface of the platform corresponding to a bottom surface of the body, wherein the shelf further comprises:
a plurality of fans that is integrated within the body of the shelf, the platform including a first plurality of openings in the top surface and a second plurality of openings in the bottom surface, each fan of the plurality of fans being configured to, when actuated, direct air in through the second plurality of openings, through the body of the shelf, and out of the first plurality of openings toward any one or more objects or devices that are placed on, supported by, or mounted to the top surface of the platform.

8. The shelf of claim 7, further comprising:
a power distribution device that is integrated within the body, the power distribution device being configured to electrically couple and power one or more of each of the at least one power outlet or each of the plurality of fans, wherein electrical coupling between the power distribution device and the one or more of each of the at least one power outlet or each of the plurality of fans is consolidated within the body of the shelf, wherein the power distribution device comprises one or more power cables that are each configured to extend below the shelf to connect with a power outlet that is external to the telecommunications equipment mounting structure.

9. The shelf of claim 1, further comprising:
one or more network connectors, each network connector communicatively coupled to one of each power outlet or one or more receptacles among the plurality of receptacles of each power outlet, each receptacle of the one or more receptacles being configured to send status information to one or more authenticated user devices via a network connector among the one or more network connectors and via a network cable that is communicatively coupled with said network connector.

10. The shelf of claim 9, wherein the status information comprises at least one of whether a device is connected to said receptacle, whether one or more devices are connected to said power outlet, amount of power consumed by a device connected to said receptacle, average amount of power consumed by the device connected to said receptacle, amount of power consumed by the device connected to said receptacle over a first period, amount of power consumed by one or more devices connected to said power outlet, average amount of power consumed by the one or more devices connected to said power outlet, amount of power consumed by the one or more devices connected to said power outlet over a second period, or error data.

11. A telecommunications equipment mounting structure, comprising:
one or more vertical support structures;
a plurality of shelves comprising:
at least one first shelf, comprising:
a body having a front surface, a rear surface, and a platform, the platform having a top surface, the platform being configured to hold, support, and/or mount one or more telecommunications equipment on its top surface, the top surface of the platform facing a first direction that is perpendicular to each of a second direction in which the front surface of the body faces and a third direction in which the rear surface of the body faces;
one or more mounting points that are configured to mount the at least one first shelf to the one or more vertical support structures of the telecommunications equipment mounting structure; and
at least one power outlet that is integrated within the body of the at least one first shelf, each power outlet comprising a plurality of receptacles, each receptacle extending from one of the front surface or the rear surface of the body, each receptacle being arranged side by side in a horizontal direction along one of the front surface or the rear surface, and each receptacle being configured to receive and fit a power plug of an electronic device.

12. The telecommunications equipment mounting structure of claim 11, wherein the telecommunications equipment mounting structure comprises one of a two-post telecommunications equipment rack, a four-post telecommunications equipment rack, a telecommunications equipment cabinet, or a telecommunications equipment enclosure, wherein the one or more vertical support structures of the two-post telecommunications equipment rack comprise two vertical posts, wherein the one or more vertical support structures of the four-post telecommunications equipment rack comprise four vertical posts, wherein the one or more vertical support structures of the telecommunications equipment cabinet comprise one or more cabinet wall mounting structures, and wherein the one or more vertical support structures of the telecommunications equipment enclosure comprise one or more enclosure vertical mounting structures.

13. The telecommunications equipment mounting structure of claim 11, further comprising:
a set of adjustable rails that are configured to mount between the body of the shelf and the one or more mounting points, and that are configured, when installed, to enable the body of the shelf to be moved, and set or locked at two or more positions, along the second direction and/or the third direction, relative to the telecommunications equipment mounting structure.

14. The telecommunications equipment mounting structure of claim 11, wherein the platform further includes a bottom surface, the top surface of the platform corresponding to a top surface of the body, the bottom surface of the platform corresponding to a bottom surface of the body, wherein the at least one first shelf further comprises:
a plurality of fans that is integrated within the body of the at least one first shelf, the platform including a first plurality of openings in the top surface and a second plurality of openings in the bottom surface, each fan of the plurality of fans being configured to, when actuated, direct air in through the second plurality of openings, through the body of the at least one first shelf, and out of the first plurality of openings toward any one or more objects or devices that are placed on, supported by, or mounted to the top surface of the platform.

15. The telecommunications equipment mounting structure of claim 11, wherein the at least one first shelf further comprises:
a power distribution device that is integrated within the body, the power distribution device being configured to electrically couple and power one or more of each of the at least one power outlet or each of the plurality of fans, wherein electrical coupling between the power distribution device and the one or more of each of the at least one power outlet or each of the plurality of fans is consolidated within the body of the at least one first shelf, wherein the power distribution device comprises one or more power cables that are each configured to extend below the at least one first shelf to connect with a power outlet that is external to the telecommunications equipment mounting structure.

16. The telecommunications equipment mounting structure of claim 11, wherein the at least one first shelf further comprises:
one or more network connectors, each network connector communicatively coupled to one of each power outlet or one or more receptacles among the plurality of receptacles of each power outlet, each receptacle of the one or more receptacles being configured to send status information to one or more authenticated user devices via a network connector among the one or more network connectors and via a network cable that is communicatively coupled with said network connector.

17. A shelf for a telecommunications equipment mounting structure, the shelf comprising:
a body having a front surface, a rear surface, and a platform, the platform having a top surface and a bottom surface, the top surface of the platform corresponding to a top surface of the body, the bottom surface of the platform corresponding to a bottom surface of the body, the platform being configured to hold, support, and/or mount one or more telecommunications equipment on its top surface, the top surface of the platform facing a first direction that is perpendicular to each of a second direction in which the front surface of the body faces and a third direction in which the rear surface of the body faces;
one or more mounting points of one or more brackets that are configured to mount the shelf to the telecommunications equipment mounting structure;
at least one power outlet that is integrated within the body of the shelf, each power outlet comprising a plurality of receptacles, each receptacle extending from one of the front surface or the rear surface of the body, each receptacle being arranged side by side in a horizontal direction along one of the front surface or the rear surface, and each receptacle being configured to receive and fit a power plug of an electronic device; and
a plurality of fans that is integrated within the body of the shelf, the platform including a first plurality of openings in the top surface and a second plurality of openings in the bottom surface, each fan of the plurality of fans being configured to, when actuated, direct air in through the second plurality of openings, through the body of the shelf, and out of the first plurality of openings toward any one or more objects or devices that are placed on, supported by, or mounted to the top surface of the platform.

18. The shelf of claim 17, further comprising:
a set of adjustable rails that are configured to mount between the body of the shelf and the one or more mounting points, and that are configured, when installed, to enable the body of the shelf to be moved, and set or locked at two or more positions, along the second direction and/or the third direction, relative to the telecommunications equipment mounting structure.

19. The shelf of claim 17, further comprising:
a power distribution device that is integrated within the body, the power distribution device being configured to electrically couple and power one or more of each of the at least one power outlet or each of the plurality of fans, wherein electrical coupling between the power distribution device and the one or more of each of the at least one power outlet or each of the plurality of fans is consolidated within the body of the shelf, wherein the power distribution device comprises one or more power cables that are each configured to extend below the shelf to connect with a power outlet that is external to the telecommunications equipment mounting structure.

20. The shelf of claim 17, further comprising:
one or more network connectors, each network connector communicatively coupled to one of each power outlet or one or more receptacles among the plurality of receptacles of each power outlet, each receptacle of the one or more receptacles being configured to send status information to one or more authenticated user devices via a network connector among the one or more network connectors and via a network cable that is communicatively coupled with said network connector.
